(19) United States
(12) Patent Application Publication
(10) Pub. No.: US 2025/0380385 A1
(43) Pub. Date: Dec. 11, 2025

(54) THERMAL HEAT TRANSFER ASSEMBLY

(71) Applicant: PLUME DESIGN, INC., Palo Alto, CA (US)

(72) Inventors: Ming-Tsung SU, Taipei City (TW); Chun Hung LIU, Taipei City (TW)

(21) Appl. No.: 18/734,213

(22) Filed: Jun. 5, 2024

(51) Int. Cl. H05K 7/20

(52) U.S. Cl. CPC H05K 7/2039; H05K 7/20154

(57) ABSTRACT

A thermal transfer device for thermally conducting heat from a heat source includes a first heat sink member arranged at a first side and a second heat sink member arranged at a second side opposite the first side. The thermal transfer device includes a first plate, at least one sidewall extending towards the second side from the first plate, and a plurality of fins. The second heat sink member includes a second plate. The first heat sink member and the second heat sink member can be in thermal connection with each other at a contact area for thermally conducting heat from the first heat sink member to the second heat sink member. The second plate is configured to distribute heat thermally conducted from the first heat sink member throughout the second plate.

### FIELD

The present disclosure relates to the field of electrical devices. More particularly, to thermal heat transfer assemblies for dissipating heat from electronic components.

### BACKGROUND

Electronic devices can be utilized in a widespread number of applications such as, for example, modems, routers, Wi-Fi nodes, monitoring devices, and the like. The electronic devices typically include therein on e or more electronic components to perform operations such as, for example, powering the device and controlling device operation. During device operation, the electronic components can generate heat, which can potentially cause irreparable damage to the electronic device. To prevent overheating and to prevent damage from occurring to the electronic components, cooling can be provided at the electronic device.

### SUMMARY

In some embodiments, a system includes a thermal transfer device having a first side and a second side, the thermal transfer device including a first heat sink member arranged at the first side and including a first plate, at least one sidewall extending towards the second side from the first plate, and a plurality of fins, and a second heat sink member arranged at the second side and including a second plate, the first heat sink member and the second heat sink member being configured to be in thermal connection with each other at a contact area for thermally conducting heat from the first heat sink member to the second heat sink member.

In some embodiments, a surface of the first heat sink member contacts a surface of the second heat sink member at the contact area.

In some embodiments, a portion of the surface of the at least one sidewall facing the second side contacts a portion of the surface of the second plate facing the first side at the contact area, and the contact area is an arcuate shape.

In some embodiments, the system further includes a fan assembly arranged between the first plate and the second plate, the fan assembly including a base member, a fan blade, and a motor, and the fan assembly being configured to direct cooling air across respective surfaces of the first heat sink member and the second heat sink member to increase a heat dissipation at the first heat sink member and the second heat sink member.

In some embodiments, the plurality of fins perpendicularly extend from at least one of the first plate and the at least one sidewall.

In some embodiments, the second plate is configured to distribute heat thermally conducted from the first heat sink member throughout the second plate.

In some embodiments, the system further including at least one thermal heat source, the first heat sink member being configured to be in thermal connection with at least one heat source at the first side for thermally conducting heat from the at least one thermal heat source throughout the first heat sink member.

In some embodiments, the at least one thermal heat source is in colinear alignment with the at least one sidewall, and the at least one sidewall is in thermal connection with the second heat sink member at the contact area for thermally conducting heat from the at least one thermal heat source to the second member through the at least one sidewall.

In some embodiments, the second plate is a copper plate having a thickness of less than 0.5 mm.

In some embodiments, the thickness of the second plate is approximately 0.2 mm.

In some embodiments, the second plate consists essentially of copper.

In some embodiments, the first heat sink member includes one or more bores extending at least partially through the at least one sidewall from the second side towards the first side, the second heat sink member includes one or more screw holes extending through the second plate, each screw hole being in colinearly alignment with a respective bore of the one or more bores, and the first heat sink member being configured to be fixedly attached to the second heat sink member using one or more fasteners installed into respective screw holes of the second heat sink member and respective bores of the first heat sink member.

In some embodiments, a thermal transfer device includes a first side, a second side opposite the first side, a first heat sink member arranged at the first side and including a first plate, at least one sidewall extending towards the second side from the first plate, and a plurality of fins, the first heat sink member being configured to be in thermal connection with at least one thermal heat source at the first side for thermally conducting heat from the at least one thermal heat source throughout the first heat sink member, and a second heat sink member arranged at the second side and including a second plate, thermal conduction of heat from the first heat sink member to the second heat sink member being configured to occur at a contact area, and the second plate being configured to distribute heat thermally conducted from the first heat sink member throughout the second plate.

In some embodiments, a portion of a surface of the at least one sidewall facing the second side contacts a portion of a surface of the second plate facing the first side at the contact area, the contact area having an arcuate shape.

In some embodiments, the at least one thermal heat source is in colinear alignment with the at least one sidewall, and the at least one sidewall is in thermal connection with the second heat sink member at the contact area for thermally conducting heat from the at least one thermal heat source to the second member through the at least one sidewall.

In some embodiments, a fan assembly is configured to be installed between the first plate and the second plate and direct cooling air across respective surfaces of the first heat sink member and the second heat sink member.

In some embodiments, the plurality of fins perpendicularly extend from at least one of the first plate and the at least one sidewall, and the plurality of fins are integrally formed with the at least one sidewall and the first plate.

In some embodiments, the second plate is a copper plate having a thickness of less than 0.5 mm.

In some embodiments, the second plate has a thickness of approximately 0.2 mm.

In some embodiments, the first heat sink member includes one or more bores extending at least partially through the at least one sidewall from the second side towards the first side, the second heat sink member includes one or more screw holes extending through the second plate, each screw hole being in colinearly alignment with a respective bore of the one or more bores, the first heat sink member being configured to be fixedly attached to the second heat sink member using one or more fasteners installed into respective screw holes of the second heat sink member and respective bores of the first heat sink member.

### BRIEF DESCRIPTION OF THE DRAWINGS

Some embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes apparent to those skilled in the art how embodiments of the disclosure may be practiced.

FIG. 1 is a perspective view illustrating a system for providing thermal heat transfer using heat sinks, according to some embodiments.

FIG. 2 is a top view of the system, according to some embodiments.

FIG. 3 is a sectional perspective view of the system, according to some embodiments.

FIG. 4 is a sectional side view of the system, according to some embodiments.

FIG. 5 is an exploded perspective view of the thermal heatsink assembly, according to some embodiments.

FIG. 6 is a graphical diagram illustrating a circulation of cooling air in the system, according to some embodiments.

### DETAILED DESCRIPTION

Electronic devices typically include one or more heat sources that generate heat during operation. The heat source can be, for example, an electrical component located on a printed circuit board in the device. The heat produced by the heat source can gradually build up during operation, causing a temperature in the device and/or at the heat source to also increase. The rate at which the temperature increases can vary based on one or more factors including, but not limited to, length of use, frequency, load demand, age, wear, ventilation, accumulation of dust or debris, electrical power demand, other like factors, or any combinations thereof. Excessive heat buildup in the device can oftentimes cause premature degradation and/or damage to the device and the components therein.

Various embodiments of the present disclosure relate to systems, devices, and apparatus for thermally conducting heat from at least one heat source in a system such as, for example, an electronic device. The at least one heat source can be an electrical component including, but not limited to, a processor, memory, antenna, graphics processor, other like components, or any combinations thereof. For example, the at least one heat source can be an antenna configured to provide the device with wireless electronic communication capabilities.

According to some embodiments, a thermal transfer device can include a first heat sink member arranged at the first side and including a first plate, at least one sidewall extending towards the second side from the first plate, and a plurality of fins, and a second heat sink member arranged at the second side and including a second plate, the first heat sink member and the second heat sink member being configured to be in thermal connection with each other at a contact area for thermally conducting heat from the first heat sink member to the second heat sink member. The embodiments of the present disclosure can improve the thermal conduction of heat generated by the at least one heat source to the thermal transfer device, and the improved dissipation of the heat by the thermal transfer device. To accomplish this, the second heat sink member is configured to thermally contact the first heat sink member at the contact area, and the second heat sink member is configured to distribute the heat thermally conducted, i.e., received, from the first heat sink member throughout the second heat sink member. In some embodiments, the at least one heat source can be in thermal contact with the first heat sink member at a first side of the thermal transfer device in colinear alignment with the at least one sidewall. The second heat sink member can be in thermal contact with a surface of the at least one sidewall for thermally conducting the heat from the at least one heat source to the second heat sink member through the at least one sidewall of the first heat sink member.

The embodiments of the present disclosure can also improve the thermal conduction of heat generated by the at least one heat source to the thermal transfer device while being capable of adapting to existing system architectures and/or without necessitating increasing the space required for implementation and effective operation. In this regard, the system can include a fan assembly arranged between the first heat sink member and the second heat sink member of the thermal transfer device, the fan assembly being configured to circulate cooling air through the system. The at least one sidewall of the first heat sink member extends from a plate of the first heat sink member towards a second side of the thermal transfer device and is in thermal connection with the second heat sink member at the contact area. The second heat sink member can be a plate including dimensions suitable for installation into the system opposite the fan assembly from the first plate member, being placed in thermal contact with the first heat sink member for thermally conducting heat from the first heat sink member, and dissipating the heat received from the first heat sink member across the second heat sink member. In addition, the heat dissipation capabilities of the second heat sink member can further be enhanced as a result of the fan assembly operation. That is, the second heat sink member is located adjacent the fan assembly, and the fan assembly can circulate cooling air across the surface of the second heat sink member to improve the thermal heat dissipation through convection. provides improved thermal conduction capabilities by fan assembly can be

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

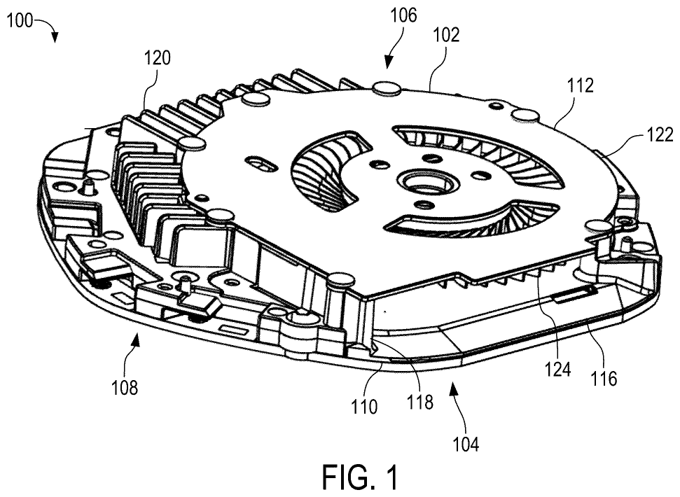

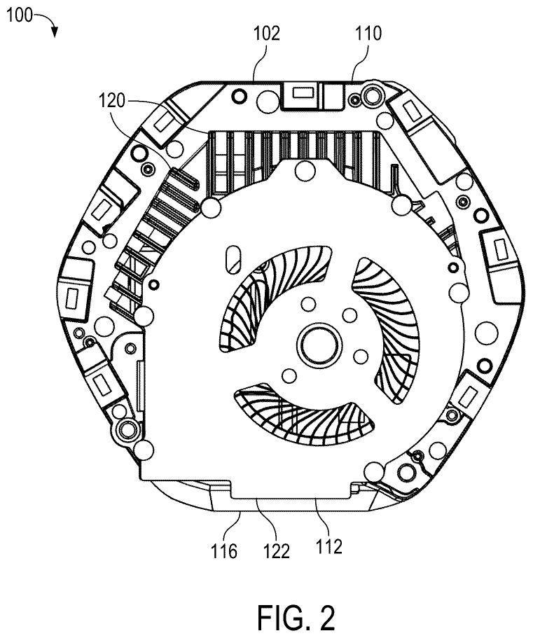

FIG. 1 is a perspective view illustrating a system 100 for thermally conducting heat from a heat source, according to some embodiments. FIG. 2 is a top view of the system 100, according to some embodiments. Unless specifically referenced, FIGS. 1 and 2 will be described collectively.

The system 100 can include a housing (not shown) and one or more components located in the housing, as will be further described herein. The system 100 can be, for example, an electronic device including one or more electronic components located within the housing, at least one of the electronic components being configured to generate heat during operation.

The system 100 includes a thermal transfer device 102 having a first side 104 and a second side 106. The thermal transfer device 102 is configured to dissipate heat in the system 100. The thermal transfer device 102 is configured to dissipate heat in the system 100 by being in thermal contact with at least one heat source 108, and thermally transferring heat generated by the at least one heat source 108 to a rest of the thermal transfer device 102, as will be further described herein.

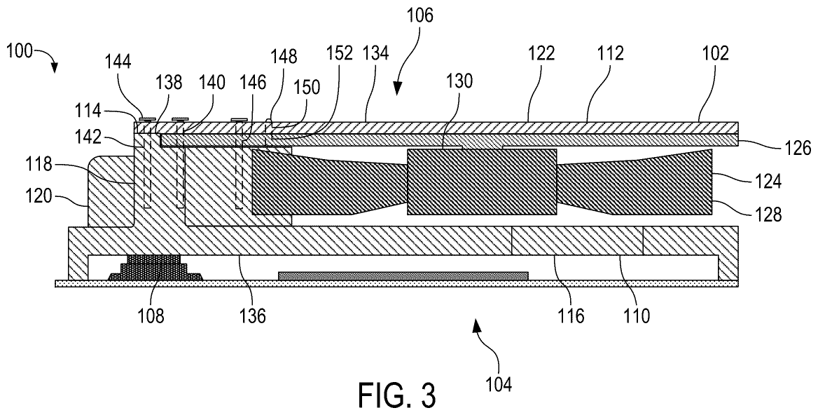

The thermal transfer device 102 includes a first heat sink member 110 and a second heat sink member 112. The first heat sink member 110 is arranged at the first side 104 and the second heat sink member 112 is arranged at the second side 106. The first heat sink member 110 and the second heat sink member 112 are configured to be in thermal connection with each other at a contact area 114 (FIG. 3) for thermally conducting heat from the first heat sink member 110 to the second heat sink member 112. The first heat sink member 110 includes a first plate 116, at least one sidewall 118, and a plurality of fins 120. The first plate 116 is arranged adjacent the first side 104, and the first plate 116 extends on a first plane.

The at least one sidewall 118 extends from the first plate 116 towards the second side 106. In this regard, the second heat sink member 112 can be fixedly connected to the first heat sink member 110 so that the at least one sidewall 118 is located between the first plate 116 and the second heat sink member 112. In some embodiments, the at least one sidewall 118 can include an arcuate shape. In other embodiments, at least a portion of the at least one sidewall 118 can include the arcuate shape. In some embodiments, the first heat sink member 110 can include a plurality of sidewalls extending from the first plate 116 and towards the second side 106, the plurality of sidewalls including the at least one sidewall 118. It is to be appreciated that the at least one sidewall 118 can further include any other suitable profiles to allow the at least one sidewall 118 to extend from the first plate 116 towards the second side 106 and around other components of the system 100, in accordance with the present disclosure.

The first heat sink member 110 is configured to be in thermal connection with the second heat sink member 112 at the contact area 114. The first heat sink member 110 can be in thermal connection with the second heat sink member 112 by a portion of a surface of the first heat sink member 110 contacting a portion of a surface of the second heat sink member 112 at the contact area 114. In some embodiments, a portion of a surface of the at least one sidewall 118 facing the second side 106 can contact a portion of a surface of the second heat sink member 112 facing the first side 104 at the contact area 114 so that the first heat sink member 110 is in thermal connection with the second heat sink member 112.

The first heat sink member 110 includes a plurality of fins 120. The plurality of fins 120 are configured to dissipate heat in the first heat sink member 110 that is transferred from the at least one heat source 108 to the first heat sink member 110. The plurality of fins 120 can perpendicularly extend from a respective plane of at least one of the first plate 116 (e.g., first plane) and the at least one sidewall 118. In some embodiments, the plurality of fins 120 can extend in a direction perpendicular to the plane of the first plate 116. In other embodiments, the plurality of fins 120 can extend in a direction perpendicular to the plane of the at least one sidewall 118. In some embodiments, the plurality of fins 120 can extend in a direction perpendicular to the plane of the first plate 116 and perpendicular to the plane of the at least one sidewall 118. In this regard, each fin 120 of the plurality of fins 120 can extend along a respective plane in a respective direction that is perpendicular to both the plane of the first plate 116 and the plane of the at least one sidewall 118. In some embodiments, each fin 120 can extend along a respective plane in a respective direction that is perpendicular to the plane of the first plate 116 and perpendicular to the plane of the corresponding section of the at least one sidewall 118 from which the respective fin is attached.

The plurality of fins 120 can extend from at least one of the first plate 116 and the at least one sidewall 118. In this regard, the plurality of fins 120 can allow for dissipating heat from at least one of the first plate 116 and the at least one sidewall 118 by dissipating heat in the plurality of fins 120 through thermal convection. In some embodiments, the first plate 116, at least one sidewall 118, and the plurality of fins 120 can be formed from a single member. For example, a single blank piece can be machined to form the first heat sink member 110 and the one or more portions thereof including, but not limited to, the first plate 116, at least one sidewall 118, and the plurality of fins 120. In other embodiments, the first heat sink member 110 can be formed from one or more components respective components that are then connected together to form the first heat sink member 110. For example, the at least one sidewall 118 can be formed so as to include the plurality of fins 120 thereon and the at least one sidewall 118 can be welded onto the first plate 116 to attach the first plate 116, the at least one sidewall 118, and the plurality of fins 120.

The second heat sink member 112 is arranged at the second side 106. The second heat sink member 112 includes a second plate 122. The second heat sink member 112 extends on a respective plane (e.g., second plane). In addition, in some embodiments, when the second heat sink member 112 is placed in thermal connection with the first heat sink member 110, the second heat sink member 112 can be positioned in the system 100 so that the plane of the second heat sink member 112 is parallel with the plane of the first plate 116. In this regard, in some embodiments, the space located between the first plate 116 of the first heat sink member 110, the second plate 122 of the second heat sink member 112, and the at least one sidewall 118 can form a fan chamber for a fan assembly 124.

It is to be appreciated that the dimensions of the thermal transfer device 102 including the first heat sink member 110 and the second heat sink member 112, or one or more portions thereof, are exemplary and not intended to be limiting. In this regard, it is also to be appreciated that the dimensions of the thermal transfer device 102 can be based on any of a plurality of factors including, but not limited to, dimensions of the system 100 or the housing, normal operating temperature, threshold temperature, thermal cooling characteristics or performance, available space, other like factors, or any combinations thereof.

System 100 can include a fan assembly 124. The fan assembly 124 can be arranged between the first heat sink member 110 and the second heat sink member 112. That is, the fan assembly 124 can be located between the first plate 116 of the first heat sink member 110 and the second plate 122 of the second heat sink member 112. The fan assembly 124 includes a base member 126, a fan blade 128, and a motor 130. The motor 130 of the fan assembly 124 is configured to rotate the fan blade 128 so as to direct cooling air across a respective surface of the first heat sink member 110 and the second heat sink member 112 to increase heat dissipation at the first heat sink member 110 and the second heat sink member 114. In addition, to reduce an ambient temperature of the system 100, the fan assembly 124 can be configured to circulate cooling air pulled in from external the system 100 to the one or more regions of the system 100. For example, in some embodiments, the rotation of the fan blade 128 by the motor 130 can cause air externally located relative to the housing of system 100 to be drawn into the housing through one or more openings or vents to provide thermal cooling to the one or more components therein, the one or more components including, but not limited to, the thermal transfer device 102, at least one heat source 108, other electrical components, one or more portions thereof, or any combinations thereof. As a result of the fan assembly 124 operation, air can be directed across a respective surface of the first heat sink member 110 and the second heat sink member 112 to provide cooling and dissipate heat that can build up in the thermal transfer device 102.

FIG. 3 is a sectional side view of the system 100, according to some embodiments.

The thermal transfer device 102 includes the first heat sink member 110 and the second heat sink member 112 configured to be in thermal contact with each other. A surface of the first heat sink member 110 is configured to contact a surface of the second heat sink member 112 at a contact area 114 so as to allow thermal heat transfer between the first heat sink member 110 and the second heat sink member 112. In some embodiments, a portion of the surface of the at least one sidewall 118 facing the second side 106 contacts a portion of the surface of the second plate 122 facing the first side 104 at the contact area 114.

The first heat sink member 110 is configured to absorb heat including heat which is generated by the at least one heat source 108. In addition, the heat in the first heat sink member 110 can build up (e.g., accumulate) in one or more portions of the first heat sink member 110 including, but not limited to, the first plate 116, at least one sidewall 118, other portions, or any combinations thereof. At least a portion of the heat that builds up in the first heat sink member 110 can be configured to be dissipated by the plurality of fins 120, thermal transfer to the second heat sink member 112, thermal convection with air surrounding the first heat sink member 110, in response to air circulation across a surface of the first heat sink member 110, or any combinations thereof. For example, the fan assembly 124 can circulate air across a surface of the first plate 116 facing the fan assembly 124 to dissipate the heat through thermal convection.

In this regard, the second heat sink member 112 is configured to absorb heat including heat which is at the first heat sink member 110. The second heat sink member 112 is configured to absorb heat through thermal heat transfer from the first heat sink member 110 to the second heat sink member 112 at the contact area 114. The second heat sink member 112 can be configured to distribute the heat in the second heat sink member 112 across the second plate 122. That is, in some embodiments, the second plate 122 can be configured to distribute heat thermally conducted from the first heat sink member 110 throughout the second plate 122. In addition, at least a portion of the heat that builds up in the second heat sink member 112 can be configured to be dissipated by thermal convection with air surrounding the first heat sink member 110, in response to air circulation across a surface of the first heat sink member 110, or any combinations thereof. For example, the fan assembly 124 can circulate air across a surface of the second plate 122 facing the fan assembly 124 to dissipate the heat in the second heat sink member 112 through thermal convection.

It is to be appreciated that the size, shape, and dimensions of the first heat sink member 110, second heat sink member 112, or one or more portions thereof, can be configured so as to provide the thermal transfer device 102 with a desired thermal heat transfer performance and characteristics. It is also to be appreciated that the size, shape, and dimensions of the first heat sink member 110, second heat sink member 112, or one or more portions thereof can also be based on the different applications of the thermal transfer device 102 and the system 100. For example, the dimensions of the thermal transfer device 102 can be based on the dimensions of the housing and other components located in the housing of the system 100.

The contact area 114, where a surface of the first heat sink member 110 contacts the second heat sink member 112 so that thermal heat transfer can occur between the members, can have one or more shapes. In some embodiments, the contact area 114 can be a planar area having one or more shapes. In other embodiments, at least a portion of the contact area 114 can be substantially planar. The contact area 114 can be one or more shapes including, but not limited to, square, rectangular, polygonal, circular, oval, arcuate, other shapes, or any combinations thereof. In some embodiments, the contact area 114 is an arcuate shape. In some embodiments, the shape of the contact area 114 can correspond to a raised (e.g., protruding) surface located on the first heat sink member 110, or one or more portions thereof, as will be further described herein.

It is to be appreciated that the size, shape, and dimensions of the contact area 114 can be based on the other portions of the thermal transfer device 102 or the system 100. For example, the size, shape, and dimensions of the contact area 114 can be based on the first heat sink member 110, first plate 116, at least one sidewall 118, second heat sink member 112, second plate 122, other members, or any combinations thereof. It is also to be appreciated that the size, shape, and dimensions of the contact area 114 can be based on one or more factors including, but not limited to, a desired thermal transfer performance and characteristics of the thermal transfer device 102.

The first heat sink member 110 can have a first thermal conductivity to transfer heat from the at least one heat source 108 and to distribute the heat throughout the first heat sink member 110 including at least the at least one sidewall 118. The second heat sink member 112 can have a second thermal conductivity to transfer heat from the first heat sink member 110 and to distribute the heat throughout the second heat sink member 112. In some embodiments, the second thermal conductivity of the second heat sink member 112 can be higher than the first thermal conductivity of the first heat sink member 110 to facilitate the thermal transfer of heat from the first heat sink member 110 to the second heat sink member 112 at the thermal transfer device 102 and for the second heat sink member 112 to dissipate the heat therein.

In this regard, the first heat sink member 110 can be made of a first metallic material 134 to provide the first heat sink member 110 with the first thermal conductivity and the second heat sink member 112 can be made of a second metallic material 136 to provide the second heat sink member 112 with the second thermal conductivity. In some embodiments, the first metallic material 134 can include stainless steel. In other embodiments, the first metallic material 134 can consist essentially of stainless steel. In yet other embodiments, the first metallic material 134 can include any of a plurality of materials including, but not limited to, steel, stainless steel, iron, nickel, chromium, aluminum, carbon, molybdenum, fillers, other metallic materials, or any combinations thereof. In some embodiments, the second metallic material 136 can include copper. In other embodiments, the second heat sink member 112 can consist essentially of copper. For example, in some embodiments, the second metallic material 136 used to form the second heat sink member 112 can be C1100.

The second heat sink member 112 can have a certain thickness so that the heat that is received from the first heat sink member 110 to the second heat sink member 112 at the contact area 114 can spread throughout the second heat sink member 112, or one or more portions thereof. The second heat sink member 112 can have a thickness of 0.1 mm to 5 mm, or any range or subrange therebetween. In some embodiments, the second heat sink member 112 can have a thickness of 0.1 mm to 5 mm, 0.2 mm to 5 mm, 0.3 mm to 5 mm, 0.4 mm to 5 mm, 0.5 mm to 5 mm, 0.6 mm to 5 mm, 0.7 mm to 5 mm, 0.8 mm to 5 mm, 0.9 mm to 5 mm, 1 mm to 5 mm, 2 mm to 5 mm, 3 mm to 5 mm, 4 mm to 5 mm, 0.1 mm to 4 mm, 0.2 mm to 4 mm, 0.3 mm to 4 mm, 0.4 mm to 4 mm, 0.5 mm to 4 mm, 0.6 mm to 4 mm, 0.7 mm to 4 mm, 0.8 mm to 4 mm, 0.9 mm to 4 mm, 1 mm to 4 mm, 2 mm to 4 mm, 3 mm to 4 mm, 0.1 mm to 3 mm, 0.2 mm to 3 mm, 0.3 mm to 3 mm, 0.4 mm to 3 mm, 0.5 mm to 3 mm, 0.6 mm to 3 mm, 0.7 mm to 3 mm, 0.8 mm to 3 mm, 0.9 mm to 3 mm, 1 mm to 3 mm, 2 mm to 3 mm, 0.1 mm to 2 mm, 0.2 mm to 2 mm, 0.3 mm to 2 mm, 0.4 mm to 2 mm, 0.5 mm to 2 mm, 0.6 mm to 2 mm, 0.7 mm to 2 mm, 0.8 mm to 2 mm, 0.9 mm to 2 mm, 1 mm to 2 mm, 0.1 mm to 1 mm, 0.2 mm to 1 mm, 0.3 mm to 1 mm, 0.4 mm to 1 mm, 0.5 mm to 1 mm, 0.6 mm to 1 mm, 0.7 mm to 1 mm, 0.8 mm to 1 mm, 0.9 mm to 1 mm, 1 mm to 1 mm, 0.1 mm to 0.9 mm, 0.2 mm to 0.9 mm, 0.3 mm to 0.9 mm, 0.4 mm to 0.9 mm, 0.5 mm to 0.9 mm, 0.6 mm to 0.9 mm, 0.7 mm to 0.9 mm, 0.8 mm to 0.9 mm, 0.1 mm to 0.8 mm, 0.2 mm to 0.8 mm, 0.3 mm to 0.8 mm, 0.4 mm to 0.8 mm, 0.5 mm to 0.8 mm, 0.6 mm to 0.8 mm, 0.7 mm to 0.8 mm, 0.1 mm to 0.7 mm, 0.2 mm to 0.7 mm, 0.3 mm to 0.7 mm, 0.4 mm to 0.7 mm, 0.5 mm to 0.7 mm, 0.6 mm to 0.7 mm, 0.1 mm to 0.6 mm, 0.2 mm to 0.6 mm, 0.3 mm to 0.6 mm, 0.4 mm to 0.6 mm, 0.5 mm to 0.6 mm, 0.1 mm to 0.5 mm, 0.2 mm to 0.5 mm, 0.3 mm to 0.5 mm, 0.4 mm to 0.5 mm, 0.1 mm to 0.4 mm, 0.2 mm to 0.4 mm, 0.3 mm to 0.4 mm, 0.1 mm to 0.3 mm, 0.2 mm to 0.3 mm, or 0.1 mm to 0.2 mm. In some embodiments, the second heat sink member 112 can have a thickness of greater than 5 mm. In other embodiments, the second plate 122 of the second heat sink member 112 can have a thickness of less than 0.5 mm. In some embodiments, the second heat sink member 112 can have a thickness of 0.2 mm. For example, the second heat sink member 112 can be a copper plate having a thickness of 0.2 mm. In another example, the second heat sink member 112 can be a copper plate having a thickness of 0.28 mm.

The system 100 includes at least one heat source 108, which can also be referred to as a thermal heat source. The first heat sink member 110 is configured to be in thermal connection with the at least one heat source 108 for thermally conducting heat transferred from the at least one heat source 108 throughout the first heat sink member 110. The at least one heat source 108 is arranged relative the first heat sink member 110 so as to be in thermal contact with the first heat sink member 110. In some embodiments, the at least one heat source 108 can be arranged adjacent the first side 104 of the thermal transfer device 102 and in thermal contact with the first heat sink member 110 at the first side 104 for thermally conducting heat from the at least one heat source 108 throughout the first heat sink member 110. In some embodiments, the at least one heat source 108 can be arranged adjacent the first side 104 and in thermal contact with a surface of the first plate 116 facing the first side 104. In some embodiments, the at least one heat source 108 can be directly contacting a surface of the first heat sink member 110. In other embodiments, the at least one heat source 108 can be in thermal contact with a respective surface of the first heat sink member 110 through an intermediate thermally conductive material such as, for example, grease, paste, polyurethane, silicone, epoxy, adhesives, glue, pads, films, other types of thermally conductive materials, or any combinations thereof.

In addition, in some embodiments, the at least one heat source 108 can be arranged relative the first heat sink member 110 so as to be in colinear alignment with the at least one sidewall 118. That is, in some embodiments, the at least one heat source 108 can be positioned at the surface of the first plate 116 facing the first side 104 and thermally contacting a portion of the surface of the first plate 116 that is in colinear alignment with the at least one sidewall 118 opposite the first plate 116. In this regard, the at least one sidewall 118 can be arranged at the first heat sink member 110 so as to be in colinear alignment with a portion of the surface of the first plate 116 that is configured to be in thermal contact with the at least one heat source 108 for thermally conducting heat from the at least one heat source 108 to the second heat sink member 112 through the at least one sidewall 118. In some embodiments, the system 100 can include one or more heat sources 108 in thermal contact with the first plate 116 at the first side 104 and the at least one sidewall 118 can be configured so as to be in colinear alignment with at least one of the heat sources 108.

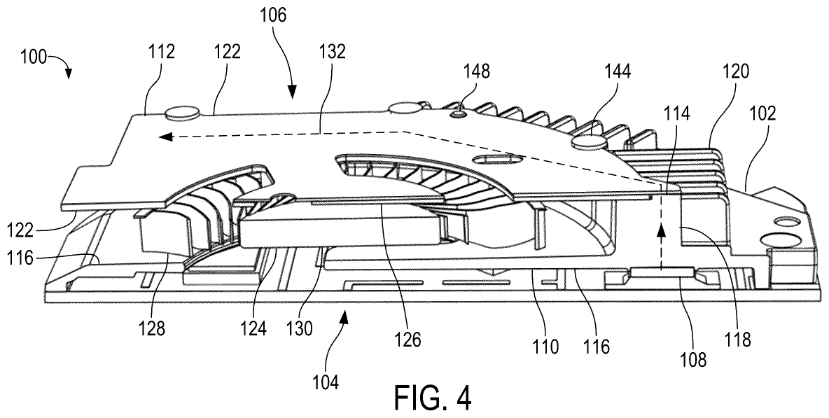

FIG. 4 is an exposed side view of the system 100, according to some embodiments.

As a result of the at least one sidewall 118 being in colinear alignment with the at least one heat source 108 and the second heat sink member 112 being in thermal contact with a surface of the at least one sidewall 118 facing the second side 106 at the contact area 114, which is opposite the at least one heat source 108, a heat transfer path 132 can be defined through the thermal transfer device 102. The heat transfer path 132 enables at least a portion of the heat in the first heat sink member 110, which was produced by the at least one heat source 108, to be directed through the first plate 116, the at least one sidewall 118, and through the second heat sink member 112. In some embodiments, a remaining portion of the heat in the first heat sink member 110 can be directed to one or more other portions of the first heat sink member 110 based on the dimensions and/or configuration of the first heat sink member 110 including, for example, throughout the first plate 116, the plurality of fins 120, and any other portions of the first heat sink member 110.

The system 100 can further include the fan assembly 124. The fan assembly 124 includes base member 126, fan blade 128, and motor 130. The fan assembly 124 can be located between the first heat sink member 110 and the second heat sink member 112. In some embodiments, the fan assembly 124 can be located between the first plate 116 and the second plate 122. The fan assembly 124 is configured to direct air across respective surfaces of the first heat sink member 110 and the second heat sink member 112 to provide cooling by dissipating the heat in the first heat sink member 110 and the second heat sink member 112.

In some embodiments, the surface of the at least one sidewall 118 facing the second side 106 can include a stepped portion 138, which is raised up higher than the rest of the surface of the at least one sidewall 118. This stepped portion 138 can define the contact area 114 where the surface of the first heat sink member 110 is in thermal contact with the second heat sink member 112. The base member 126 can be arranged adjacent the stepped portion 138 so that the fan assembly 124 can be mounted to the thermal transfer device 102.

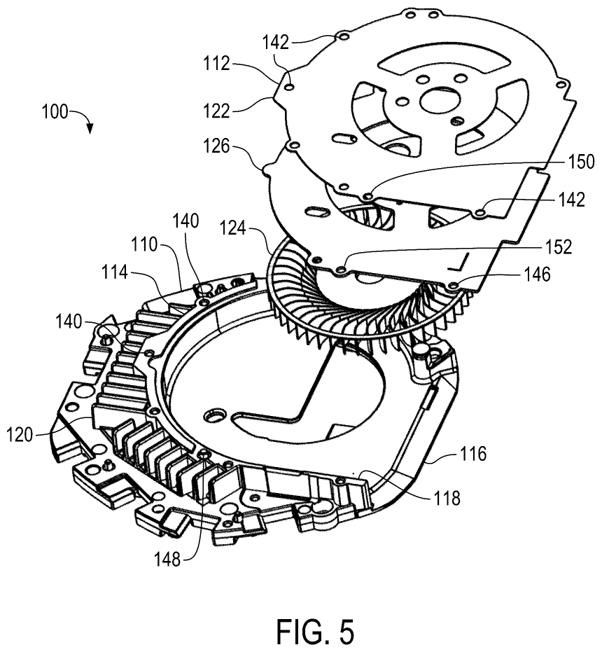

FIG. 5 is an exploded perspective view of a portion of the system 100, according to some embodiments.

As shown in FIG. 5, the contact area 114 can have an arc-shape (e.g., arcuate), according to some embodiments. In some embodiments, the shape of the contact area 114 can be dependent on the size, shape, and dimensions of the at least one sidewall 118. That is, in some embodiments, the at least one sidewall 118 can be configured to circumferentially extend around a periphery of the fan assembly 124 so as to define a fan chamber for circulating air through the system 100, and the contact area 114 can be formed on a surface of the at least one sidewall 118 facing the second side 106.

The first heat sink member 110 can include one or more bores 140 extending at least partially through the at least one sidewall 118 from the second side 106 towards the first side 104. In some embodiments, the bores 140 can extend through the first heat sink member 110 from the first side 104 to the second side 106.

The second heat sink member 112 can include one or more screw holes 142 extending through the second plate 122. Each of the screw hole 142 can be in colinear alignment with a respective bore of the one or more bores 140. The first heat sink member 110 is configured to be fixedly attached to the second heat sink member 112 using one or more fasteners 144, which can be installed into a respective screw hole 142 of the second heat sink member 112 and a respective bore 140 of the first heat sink member 110.

The first heat sink member 110 can be attached to the second heat sink member 112 using one or more fasteners 144. The fasteners 144 can include, but is not limited to, screws, bolts, nuts, clips, rivets, solder, epoxy, glue, tape, adhesive, clamps, other types of retaining members, or any combinations thereof. In some embodiments, the one or more fasteners 144 can include one or more threads formed thereon and configured to engage one or more corresponding threads formed on at least one of the bores 140 and the one or more screw holes 142 to attach the first heat sink member 110 to the second heat sink member 112.

In addition, the fan assembly 124 can be attached to the thermal transfer device 102 using the one or more fasteners 144. In some embodiments, the base member 126 can include one or more screw holes 146 extending through the base member 126. Each of the screw holes 146 can be in colinear alignment with a respective bore 140 located in the first heat sink member 110, and the fan assembly 124 can be attached to the thermal transfer device 102 by installing a fastener 144 into the screw hole 146 and into the corresponding bore 140.

The first heat sink member 110 can also include one or more guide pins 148. The guide pins 148 can be configured to aid with alignment of at least one of the second heat sink member 112 and fan assembly 124 prior to attaching a component to the first heat sink member 110. In some embodiments, the first heat sink member 110, at the at least one sidewall 118, can include the one or more guide pins 148 located on the surface of the at least one sidewall 118 facing the second side 106. The one or more guide pins 148 can extend from the surface towards the second side 106.

At least one of the second heat sink member 112 and the base member 126 of the fan assembly 124 can be configured to engage the guide pins 148 so as to aid in aligning the respective component relative the first heat sink member 110 during installation. In some embodiments, the second heat sink member 112 can include a respective aperture 150 arranged therethrough so as to be in colinear alignment with a corresponding guide pin 148, which is configured to extend through the aperture 150 when the second heat sink member 112 is in position for being attached to the first heat sink member 110. In this regard, during installation of the second heat sink member 112 onto the first heat sink member 110, the apertures 150 in the second heat sink member 112 and the corresponding guide pins 148 can aid in properly aligning the second heat sink member 112 relative to the first heat sink member 110 prior to attaching the second heat sink member 112 thereto. In other embodiments, the base member 126 can include a respective aperture 152 arranged therethrough so as to be in colinear alignment with a corresponding guide pin 148, which is configured to extend through the aperture 152 when the base member 126 is in position for being attached to the first heat sink member 110. In this regard, during installation of the fan assembly 124 onto the first heat sink member 110, the apertures 152 in the base member 126 and the corresponding guide pins 148 can aid in properly aligning the base member 126 relative to the first heat sink member 110 and the second heat sink member 112 prior to attaching the base member 126 thereto.

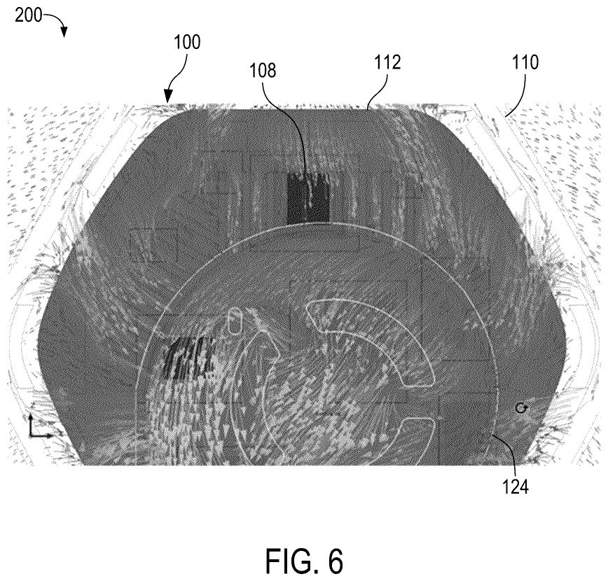

FIG. 6 is a graphical diagram 200 illustrating a circulation of cooling air in the system 100, according to some embodiments.

The fan assembly 124 is configured to direct air through system 100 and around the one or more components therein including at least one of the electrical components, the at least one heat source 108, the first heat sink member 110, the second heat sink member 112, and other components in the system 100. The fan assembly 124 can be configured so that the operation of the fan assembly 124 causes cooling air to be directed up through the fan assembly 124 from the first side 104 to the second side 106. As a result, an upper area of the fan assembly 124 adjacent the second side 106 can have strong airflow due to the air being directed to the upper area of the fan chamber. Accordingly, rotation of the fan blade 128 causes the cooling air to be directed up through the fan blade 128 and to the upper area, and the cooling air can blow/sweep the surface of the second heat sink member 112 facing the fan assembly 124 to allow for the heat that is in the second heat sink member 112 to dissipate quickly. The heat dissipation in the second heat sink member 112 from the cooling air being directed onto the surface of the second heat sink member 112 can also be facilitated by the thickness of the second heat sink member 112 being configured to allow for even faster dissipation. For example, the second heat sink member 112 can have a thickness of 0.2 mm to allow for faster heat dissipation in response to the cooling air being directed onto the surface of the second heat sink member 112 as compared with conventional heat spreaders.

The operation of the fan assembly 124 can cause cooling air to thereby be directed across a respective surface of at least one of the first plate 116 and the second plate 122 to dissipate heat in the respective component. In some embodiments, the operation of the fan assembly 124 can cause cooling air to be directed across the surface of the second plate 122 to dissipate heat in the second heat sink member 112. In other embodiments, the operation of the fan assembly 124 can also cause cooling air to be directed across the surface of the first plate 116 to dissipate heat in the first heat sink member 110. The operation of the fan assembly 124 can also cause cooling air to be directed across one or more other components in the system 100 so as to dissipate heat in those components and/or to slow the buildup of heat in those components. For example, the cooling air can improve heat dissipation at the plurality of fins 120.

All prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

As used herein, the term “between” does not necessarily require being disposed directly next to other elements. Generally, this term means a configuration where something is sandwiched by two or more other things. At the same time, the term “between” can describe something that is directly next to two opposing things. Accordingly, in any one or more of the embodiments disclosed herein, a particular structural component being disposed between two other structural elements can be:
disposed directly between both of the two other structural elements such that the particular structural component is in direct contact with both of the two other structural elements;
disposed directly next to only one of the two other structural elements such that the particular structural component is in direct contact with only one of the two other structural elements;
disposed indirectly next to only one of the two other structural elements such that the particular structural component is not in direct contact with only one of the two other structural elements, and there is another element which juxtaposes the particular structural component and the one of the two other structural elements;
disposed indirectly between both of the two other structural elements such that the particular structural component is not in direct contact with both of the two other structural elements, and other features can be disposed therebetween; or
any combination(s) thereof.

What is claimed is:

1. A system comprising:
a thermal transfer device having a first side and a second side, the thermal transfer device comprising:
a first heat sink member arranged at the first side and comprising:
a first plate,
at least one sidewall extending towards the second side from the first plate, and
a plurality of fins; and
a second heat sink member arranged at the second side and comprising:
a second plate;
wherein the first heat sink member and the second heat sink member are configured to be in thermal connection with each other at a contact area for thermally conducting heat from the first heat sink member to the second heat sink member.

2. The system of claim 1, wherein a surface of the first heat sink member contacts a surface of the second heat sink member at the contact area.

3. The system of claim 2, wherein a portion of the surface of the at least one sidewall facing the second side contacts a portion of the surface of the second plate facing the first side at the contact area, and the contact area is an arcuate shape.

4. The system of claim 1, further comprising:
a fan assembly arranged between the first plate and the second plate, the fan assembly comprising:
a base member,
a fan blade, and
a motor,
wherein the fan assembly is configured to direct cooling air across respective surfaces of the first heat sink member and the second heat sink member to increase a heat dissipation at the first heat sink member and the second heat sink member.

5. The system of claim 1, wherein the plurality of fins perpendicularly extend from at least one of the first plate and the at least one sidewall.

6. The system of claim 1, wherein the second plate is configured to distribute heat thermally conducted from the first heat sink member throughout the second plate.

7. The system of claim 1, further comprising:
at least one thermal heat source,
wherein the first heat sink member is configured to be in thermal connection with at least one heat source at the first side for thermally conducting heat from the at least one thermal heat source throughout the first heat sink member.

8. The system of claim 7, wherein the at least one thermal heat source is in colinear alignment with the at least one sidewall, and the at least one sidewall is in thermal connection with the second heat sink member at the contact area for thermally conducting heat from the at least one thermal heat source to the second member through the at least one sidewall.

9. The system of claim 1, wherein the second plate is a copper plate having a thickness of less than 0.5 mm.

10. The system of claim 9, wherein the thickness of the second plate is approximately 0.2 mm.

11. The system of claim 9, wherein the second plate consists essentially of copper.

12. The system of claim 1, wherein the first heat sink member comprises one or more bores extending at least partially through the at least one sidewall from the second side towards the first side,
wherein the second heat sink member comprises one or more screw holes extending through the second plate, each screw hole being in colinearly alignment with a respective bore of the one or more bores,
wherein the first heat sink member is configured to be fixedly attached to the second heat sink member using one or more fasteners installed into respective screw holes of the second heat sink member and respective bores of the first heat sink member.

13. A thermal transfer device comprising:
a first side;
a second side opposite the first side;
a first heat sink member arranged at the first side and comprising:
a first plate,
at least one sidewall extending towards the second side from the first plate, and
a plurality of fins;
wherein the first heat sink member is configured to be in thermal connection with at least one thermal heat source at the first side for thermally conducting heat from the at least one thermal heat source throughout the first heat sink member; and
a second heat sink member arranged at the second side and comprising:
a second plate;
wherein thermal conduction of heat from the first heat sink member to the second heat sink member is configured to occur at a contact area, and the second plate is configured to distribute heat thermally conducted from the first heat sink member throughout the second plate.

14. The thermal transfer device of claim 13, wherein a portion of a surface of the at least one sidewall facing the second side contacts a portion of a surface of the second plate facing the first side at the contact area, the contact area having an arcuate shape.

15. The thermal transfer device of claim 13, wherein the at least one thermal heat source is in colinear alignment with the at least one sidewall, and the at least one sidewall is in thermal connection with the second heat sink member at the contact area for thermally conducting heat from the at least one thermal heat source to the second member through the at least one sidewall.

16. The thermal transfer device of claim 13, wherein a fan assembly is configured to be installed between the first plate and the second plate and direct cooling air across respective surfaces of the first heat sink member and the second heat sink member.

17. The thermal transfer device of claim 13, wherein the plurality of fins perpendicularly extend from at least one of the first plate and the at least one sidewall, and the plurality of fins are integrally formed with the at least one sidewall and the first plate.

18. The thermal transfer device of claim 13, wherein the second plate is a copper plate having a thickness of less than 0.5 mm.

19. The thermal transfer device of claim 18, wherein the second plate has a thickness of approximately 0.2 mm.

20. The thermal transfer device of claim 13, wherein the first heat sink member comprises one or more bores extending at least partially through the at least one sidewall from the second side towards the first side,
wherein the second heat sink member comprises one or more screw holes extending through the second plate, each screw hole being in colinearly alignment with a respective bore of the one or more bores,
wherein the first heat sink member is configured to be fixedly attached to the second heat sink member using one or more fasteners installed into respective screw holes of the second heat sink member and respective bores of the first heat sink member.
